(19) United States
(12) Patent Application Publication
(10) Pub. No.: US 2013/0323434 A1
(43) Pub. Date: Dec. 5, 2013

(54) INKJET PRINTING WITH IN SITU FAST ANNEALING FOR PATTERNED MULTILAYER DEPOSITION

(71) Applicant: KING ABDULLAH UNIVERSITY OF SCIENCE AND TECHNOLOGY, Thuwal (SA)

(72) Inventors: Samir Boulfrad, Thuwal (SA); Erkki Alarousu, Thuwal (SA); Eman Husni Da'as, Thuwal (SA); Ghassan Jabbour, Thuwal (SA)

(73) Assignee: KING ABDULLAH UNIVERSITY OF SCIENCE AND TECHNOLOGY, Thuwal (SA)

(21) Appl. No.: 13/903,698

(22) Filed: May 28, 2013

Related U.S. Application Data
(60) Provisional application No. 61/652,351, filed on May 29, 2012.

(51) Int. Cl. B41J 3/28; H01B 13/00

(52) U.S. Cl. CPC B41J 3/28; H01B 13/0026
USPC 427/555; 118/713; 118/71; 427/559; 427/58; 427/75; 427/115

(57) ABSTRACT

Patterned multilayer films, such as those used in electronic devices, solar cells, solid oxide fuel cells (SOFCs), and solid oxide electrolysis cells (SOECs) may be deposited and annealed in a single tool. The tool includes an inkjet printer head, a heater, and a laser. The inkjet printer head deposits on a substrate either suspended particles of a functional material or solvated precursors of a functional material. The head is mounted on a support that allows the head to scan the substrate by moving along the support in a first direction and moving the support along a second direction. After the head deposits the material the heater evaporates solvent from substrate, and the depositing and heating may be repeated one or more times to form a patterned multilayer material. Then, a laser, microwave, and/or Joule effect heating device may be used to anneal the multilayer material to a desired pattern and crystalline state.

### CROSS-REFERENCE TO RELATED APPLICATIONS

This application claims the benefit of priority to U.S. Provisional Patent Application No. 61/652,351 to Samir Boulfrad et al. filed May 29, 2012, and entitled “INKJET PRINTING WITH IN SITU FAST ANNEALING FOR MULTILAYER DEPOSITION,” which is hereby incorporated by reference in its entirety.

### FIELD OF DISCLOSURE

This disclosure relates to inkjet printing and more particularly relates to inkjet printing of multilayer materials.

### BACKGROUND

Manufacturing of patterned multilayer materials for devices often includes deposition of multiple layers with other steps performed in between the deposition of the layers. For example, in one multilayer material a first layer may be deposited, followed by an annealing step, and then deposition of a second layer on top of the multilayer material. The intermediate steps, such as the annealing step, are performed using tools separate from the deposition steps due to requirements for specialty tools for performing the intermediate steps and/or cleanliness in the deposition chamber. Other examples of intermediate steps include etching, chemical mechanical polishing, and cleaning. As a device is manufactured, the device is moved from the deposition tool to other tools and back to the deposition tool. Moving the device between tools delays the manufacturing process and ultimately lowers throughput, which increases the cost of the device.

### BRIEF SUMMARY

In accordance with the present disclosure, patterned multilayer deposition and intermediate steps may be carried out in the same tool to improve throughput of the manufacturing process and decrease cost of the manufactured devices. Multilayer deposition may be performed by one or more inkjet printer heads. The inkjet printer heads may be mounted on a supporting member and movable along one dimension of the supporting member. The supporting members may be moved along a second dimension, and a third dimension, to allow the inkjet printer head to reach an appropriate distance from the printing area and to deposit materials by scanning a two dimensional area of a holder. A second supporting member may be similarly organized and support other items, such as a heater and a laser, for scanning a two dimensional area of the holder. Because both the first supporting member and the second supporting member can scan the entire area of the holder, manufacturing processing involving deposition steps and intermediate steps may be performed using the same tool.

In some embodiments, a laser is used as a source to cure printed materials. The laser provides concentrated energy to a localized area allowing rapid annealing and/or sintering of the printed material. For example, the annealing time may be under one second per square centimeter. Further, laser annealing generates heat substantially only at a surface targeted by the laser for a short time. The heat provides for local annealing and/or sintering but dissipates quickly to reduce the heating of the substrate. In some embodiments, other annealing tools may be used based on microwave or Joule effect heat generation devices.

In one embodiment, patterning is performed by an inkjet head with resolutions of few microns or smaller. According to another embodiment, laser annealing may allow sub-micron patterning within the pattern printed by the inkjet head. In another embodiment, non-annealed zones in the inkjet pattern may be cleaned with a liquid-solvent dispensing device.

An apparatus having movable supporting members for scanning items across a holder allows several processes to be performed in situ. This apparatus allows fast patterned multilayer deposition with high precision, because movement of the substrate between tools is reduced or eliminated. Moreover, the use of a laser for annealing reduces annealing times from minutes and/or hours to seconds. Such an apparatus for fast and precise deposition of patterned multilayer functional materials may be used in the electronics industry and energy industry. Specifically, the apparatus may be used for the manufacturing of fuel cells, solar cells, and printable electronics.

According to one embodiment, the apparatus may include a holder, an inkjet printer head positioned to dispense material on a substrate affixed to the holder, and optics for directing a laser beam to the substrate affixed to the holder.

In some embodiments, the apparatus may also include a heating device and/or a heated gas source for directing heated gas to the substrate affixed to the holder, a first support member oriented substantially perpendicular to a normal vector of the holder and extending along a first dimension, a second support member oriented substantially perpendicular to the normal vector of the holder and extending substantially parallel to the first support member, a track oriented substantially perpendicular to the first and second support member, a laser coupled to the optics, a vacuum system coupled to the holder, and/or a heating device coupled to the holder.

In certain embodiments, the optics include a fiber pigtailed objective lens and/or the inkjet printer head may be configured to dispense a solution comprises at least one of a solvated precursor to a functional material and a solvated particle of a functional material.

According to another embodiment, a method includes depositing a first solution on a substrate with an inkjet printer. The method may also include drying the first solution to evaporate a solvent from the first deposited solution and form a first layer. The method may further includes depositing a second solution on a substrate with the inkjet printer. The method may also include drying the second solution to evaporate a solvent from the second deposited solution and form a second layer. The method may also further include scanning a laser beam across the surface of the substrate to anneal the first layer and the second layer. In some embodiments, several cycles of depositing, drying, and annealing may be performed.

According to some embodiments, a heat treatment leading to drying and/or annealing step is performed after depositing a first solution and before depositing, drying, and annealing a second solution.

In some embodiments, the method may also include heating the substrate before and/or during the step of depositing the first solution.

In certain embodiments, the step of depositing the first solution comprises depositing at least one of a solvated precursor to a functional material and/or a suspension of particles of a functional material, the step of drying the first solution comprises evaporating the solvent, the step of scanning the laser beam across the surface comprises decomposing organic components of the first solution and the second solution, and/or the steps of depositing the first solution and/or depositing the second solution comprise depositing at least one layer of a solid oxide fuel cell and/or a solid oxide electrolysis cell.

The foregoing has outlined rather broadly the features and technical advantages of the present disclosure in order that the detailed description that follows may be better understood. Additional features and advantages of the disclosure will be described hereinafter which form the subject of the claims. It should be appreciated by those skilled in the art that the conception and specific embodiment disclosed may be readily utilized as a basis for modifying or designing other structures for carrying out the same purposes of the present disclosure. It should also be realized by those skilled in the art that such equivalent constructions do not depart from the spirit and scope of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the disclosed system and methods, reference is now made to the following descriptions taken in conjunction with the accompanying drawings.

FIG. 1 is block diagram illustrating an apparatus for depositing patterned multilayer materials with an inkjet printer head according to one embodiment of the disclosure.

FIG. 2 is block diagram illustrating the deposition of patterned multilayer materials with an inkjet printer head according to one embodiment of the disclosure.

FIG. 3 is a flow chart illustrating a method for depositing patterned multilayer materials from an inkjet printer head according to one embodiment of the disclosure.

### DETAILED DESCRIPTION

An inkjet printer head may dispense a liquid solution on a substrate, which contains solvents and either or both of particles of a functional material or precursors of a functional material. According to one embodiment, the precursors may be soluble salts such as nitrates, acetates, and/or chlorides. The solvent may be dried using static heat and/or heated gases. A method for manufacturing a patterned multilayer material may include printing from the inkjet printer head and drying, which may be repeated one or more times. Then, a laser beam may be transported through optics, such as a movable fiber pigtailed objective lens, and directed at the multilayer material to decompose organic components in the solutions and cause the multilayer material to crystallize in a desired phase and pattern. In some embodiments, microwave or Joule effect heating devices can be used instead or in addition to laser annealing. The process of depositing and annealing may be repeated with the same material to obtain thicker deposited layers and/or using a second material to fabricate multilayered systems.

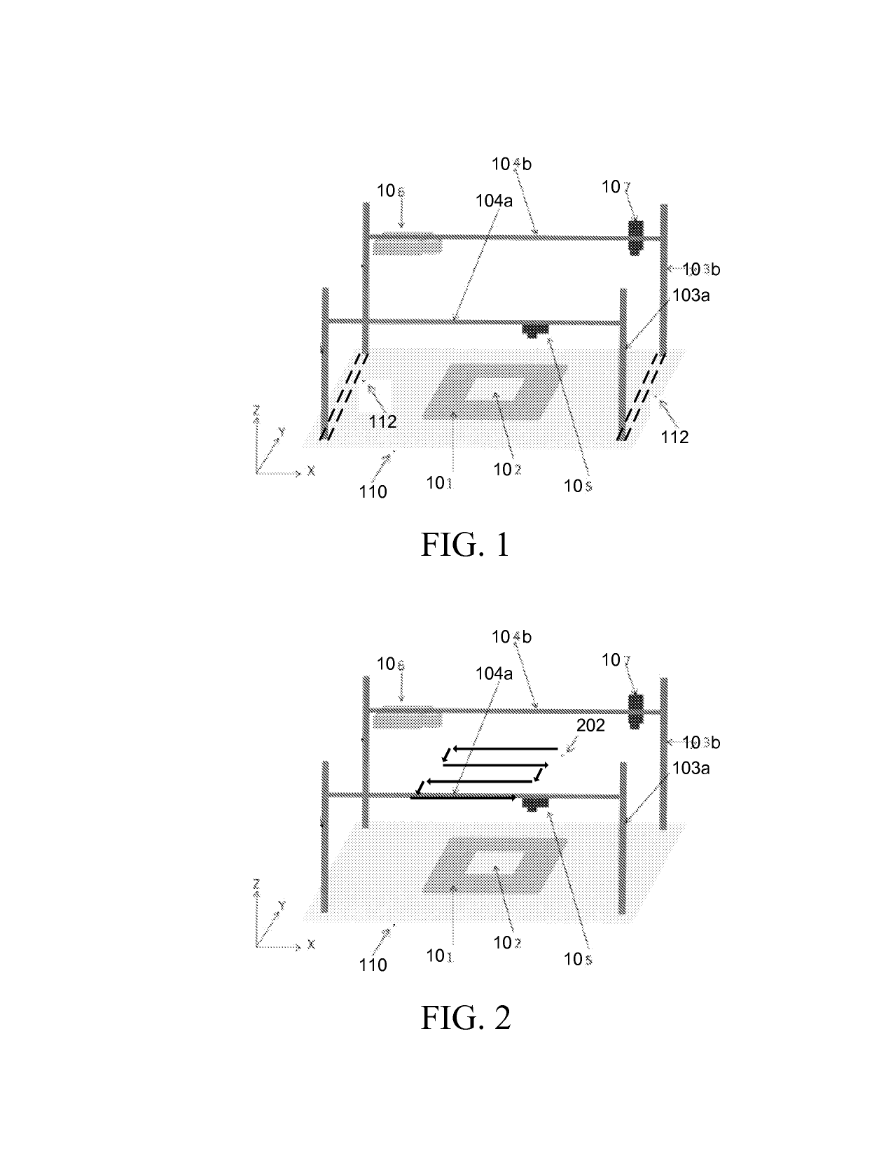

FIG. 1 is block diagram illustrating an apparatus 100 for depositing patterned multilayer materials with inkjet printer heads according to one embodiment of the disclosure. Apparatus 100 includes a first supporting member 104a and a second supporting member 104b extending along a first dimension such as the x dimension. According to one embodiment, the supporting members 104a-b are metallic or plastic circular rods. The supporting members 104a-b may be secured to posts 103a-b, respectively. In addition, the supporting members 104a-b may move in a z-dimension along the posts 103a-b. The posts 103a-b may be attached to tracks 112 in a base 110. The tracks 112 may transport the posts 103a-b, and thus the first and second supporting members 104a-b, along a y-dimension. The base 110 may also include a holder 101 for a substrate 102.

An inkjet printer head 105 may be attached to the first supporting member 104a. Although not shown, additional items, such as additional inkjet printer heads, may be attached to the first supporting member 104a. For example, a second inkjet printer head may be attached to the first supporting member 104a when deposition of a material layer on the substrate 102 involves more than one precursor material. The inkjet printer head 105 may be configured to scan across the first supporting member 104a, such as by a motorized stage controlled by external electronics (not shown). By combining movement in the x, y, and z dimensions, the inkjet printer head 105 may scan the surface area of the substrate 102. During the scanning, the inkjet printer head 105 may deposit materials, such as a solvated precursor to a functional material and/or a solvated particle of a functional material. Functional materials may include different ceramic and/or metallic materials such as oxides ZnO, (In₂O₃)_{0.9}(SnO₂)_{0.1} (ITO), La₁₋ₓSrₓMnO₃ (LSM), La₁₋ₓSrₓCo_{1-y}Fe_{y}O₃ (LSCF), La₁₋ₓSrₓCr_{1-y}Mn_{y}O₃ (LSCM), La₁₋ₓSrₓNi_{1-y}Ti_{y}O₃ (LSNT), NbTi_{0.5}Ni_{0.5}O₄ (NTNO) and metal particles (Ag, Ni, Pd, Pt, Ru, Fe, Ce).

A dryer 106 may be attached to the second supporting member 104b. The dryer 106 may include a heating element (not shown) and/or a fan for blowing heated gas across the substrate 102. Additional devices may be attached to the second supporting member 104b. For example, optics 107 for directing a laser beam may be attached to the second supporting member 104b. According to one embodiment, the optics 107 may include a fiber pigtailed objective lens and be attached to one of a pulsed laser, an 800 nm femtosecond laser, or a white light laser. The laser beam directed by the optics 107 to the substrate 102 may anneal materials deposited on the substrate 102 by the inkjet printer head 105. In addition to or instead of a laser beam for annealing, microwave and/or Joule-effect heating devices may be attached to the second supporting member 104b.

In one embodiment, a liquid-solvent dispensing device (not shown) may be attached to one supporting member. In another embodiment, the liquid-dispensing device may be a spray-generator device. According to a further embodiment, a droning system (not shown) may be coupled to the holder 101.

According to one embodiment, the holder 101 may be integrated with other components. For example, the holder 101 may be connected to a vacuum system (not shown) for providing suction to hold the substrate 102 to the holder 101. For example, holes may be drilled in the holder 101 and connected to the vacuum system. When the substrate 102 covers the holes, a force is applied to the substrate 102 to affix the substrate 102 to the holder 101. In some embodiments, the substrate 102 may be fastened to the holder 101 using clamps (not shown) or other mechanical systems with similar functionality.

According to another embodiment, the holder 101 may have an integrated heater and thermocouple. For example, a heater (not shown) may be attached to or integrated into the holder 101 to elevate the temperature of the substrate 102 during multilayer deposition. A thermocouple (not shown) connected to the holder 101 may allow temperature readings of the holder 101 and/or the substrate 102. The temperature measurements may be provided to a controller coupled to the heater in the holder 101 to maintain a nearly constant temperature at the holder 101.

In another embodiment, in addition to the movability of the above components, the holder 101 may be coupled to a motorized system to perform scanning movement along x and y directions with respect to the printing heads. In some embodiments, a moving substrate and fixed printing head may allow more accurate printed shapes and patterns.

In yet another embodiment, a camera (not shown) may be attached to one of the supporting members 103a-b or another fixture in the apparatus 100. The camera may capture images of the substrate 102 for use during maintenance or diagnostics on the apparatus 100. Further, the camera may be used to perform alignment of the inkjet deposition head 105 with the substrate 102. The camera or other additional cameras may be used to align the heater 106 and the optics 107 with the substrate 102. The camera may also be configured to provide quality control by examining the substrate before, during, and/or after deposition, drying, and/or annealing steps.

Scanning of items attached to the supporting member 104a-b and/or the holder 101 may be performed in a number of patterns and in parallel or serial sequence. FIG. 2 is block diagram illustrating the deposition of patterned multilayer materials with an inkjet printer head according to one embodiment of the disclosure. The inkjet printer head 105 may take a snake pattern 202 across the substrate 102, although other patterns would also be acceptable. The heater 106 may take a similar path to the pattern 202 of the inkjet printer head 105, after the inkjet printer head 105 completes depositing material along the pattern 202. The heater 106 may alternatively begin the pattern 202 before the inkjet printer head 105 completes the pattern 202, after sufficient time has passed that the elevated temperatures from the heater 106 do not degrade the solution stored in the inkjet printer head 105.

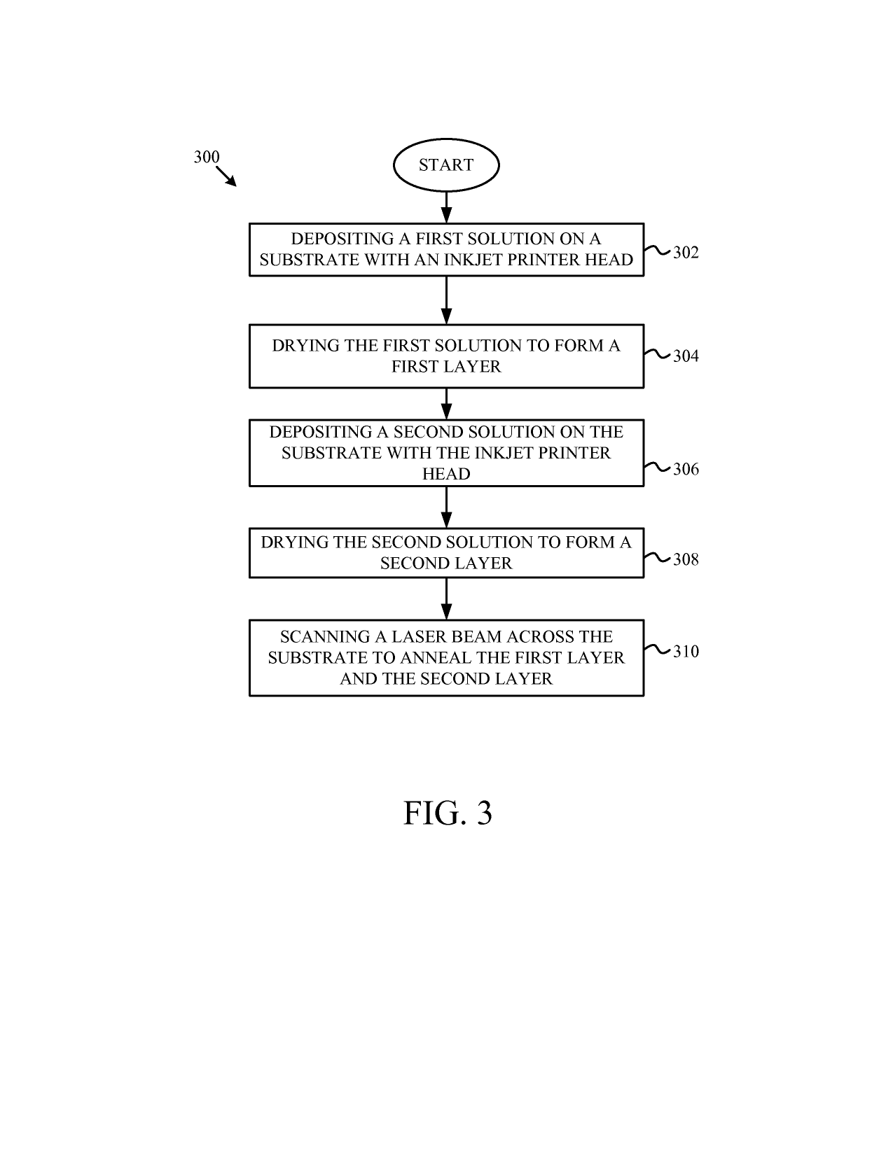

FIG. 3 is a flow chart illustrating a method for depositing patterned multilayer materials from an inkjet printer head according to one embodiment of the disclosure. A method 300 begins at block 302 with depositing a first solution on a substrate with an inkjet printer head. At block 304, the first solution is dried to form a first layer. For example, solvent from the first solution may be dried with heated air. At block 306, a second solution may be deposited on the substrate with the inkjet printer head. According to one embodiment, the second solution may be deposited from a second inkjet printer head different from the first inkjet printer head. The second inkjet printer head may be attached to the first supporting member 104a of FIG. 1 or to the second supporting member 104b or a third supporting member (not shown). At block 308, the second solution is dried to form a second layer of a multilayer material on the substrate. At block 310, a laser beam is scanned across the substrate to anneal the first layer and the second layer. According to one embodiment, the laser annealing decomposes organic components from the first and second solutions deposited on the substrate to crystallize the material in a desired phase. The crystallization and annealing may be adapted for deposition of different materials by selecting laser beams of a specific wavelength or power.

In another embodiment, step 310 may be performed using microwave or Joule-effect heating devices. In some embodiments, annealing and crystallization may be performed after deposition and drying of the first layers at blocks 302, 304, respectively, and before deposition of a second layer at block 306. In some embodiments, a cleaning step using a liquid-solvent dispensing devise on annealed first layer may be implemented before deposition of a second layer at block 306.

Multilayer deposition described above may be used to manufacture fuel cells with larger triple phase boundaries (TPBs) through impregnation. Impregnation is one method used during the manufacturing of fuel cells to increase the TPB density, which improves the electrochemical performance of the electrodes. According to one embodiment, a microporous structure of the ionic conductive phase of the electrode may be infiltrated with solutions containing liquid solvents, particles of functional materials, precursors of functional materials, dispersants, and/or surfactants. After evaporation of the solvent, the impregnated structure may be heated to a formation temperature of a coating phase. The steps of infiltration, evaporation, and/or heating may be repeated one or more times to obtain a desired structure. The impregnation process may be performed in a scalable and controlled method with multilayer deposition inkjet printing, as described above in FIGS. 1-3.

The schematic flow chart diagram of FIG. 3 is generally set forth as a logical flow chart diagram. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the present disclosure, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus, comprising:
a holder;
an inkjet printer head positioned to dispense material on a substrate affixed to the holder;
optics for directing a laser beam to the substrate affixed to the holder; and
a camera configured to provide at least one of alignment of the inkjet printer head, alignment of the optics, and quality control.

2. The apparatus of claim 1, further comprising a heating device comprising at least one of a heated gas source, a microwave heating device, and a Joule-effect heating device.

3. The apparatus of claim 2, further comprising a liquid-solvent dispensing device.

4. The apparatus of claim 3, further comprising a first support member oriented substantially perpendicular to a normal vector of the holder and extending along a first dimension, the inkjet printer head being attached to the first support member.

5. The apparatus of claim 4, the inkjet printer head being movable along the first dimension.

6. The apparatus of claim 5, further comprising a second support member oriented substantially perpendicular to the normal vector of the holder and extending substantially parallel to the first support member, the optics being attached to the second support member.

7. The apparatus of claim 6, in which the inkjet printer head, the optics, the heating device, the liquid-solvent dispensing device, and the camera are movable along a z dimension.

8. The apparatus of claim 7, further comprising a track oriented substantially perpendicular to the first and second support member, the first support member and the second support member being attached to the track and movable along a second dimension substantially perpendicular to the first dimension.

9. The apparatus of claim 1, further comprising a laser coupled to the optics, the laser generating the laser beam.

10. The apparatus of claim 8, the optics comprising a fiber pigtailed objective lens.

11. The apparatus of claim 1, further comprising a vacuum system coupled to the holder, the vacuum system being configured to assist in affixing the substrate to the holder.

12. The apparatus of claim 1, further comprising a mechanical affixing system for fixing the substrate to the holder.

13. The apparatus of claim 1, further comprising a heating device and a thermocouple, the heating device increasing the temperature of the holder and the substrate.

14. The apparatus of claim 1, further comprising a gas-tight enclosure surrounding the holder, the inkjet printer, and the optics, the gas-tight enclosure configured to provide a gas-controlled environment.

15. An apparatus, comprising:
a holder;
an inkjet printer head positioned to dispense material on a substrate affixed to the holder;
optics for directing a laser beam to the substrate affixed to the holder;
means for securing the inkjet printer head above the holder; and
means for securing the optics above the holder.

16. The apparatus of claim 15, further comprising means for scanning at least one of the inkjet printer head and the holder along a first and a second dimension.

17. The apparatus of claim 16, in which the inkjet printer head is configured to dispense a solution comprises at least one of a solvated precursor to a functional material and a suspension of particles of a functional material.

18. A method, comprising:
depositing a first solution on a substrate with an inkjet printer;
drying the first solution to evaporate a solvent from the first deposited solution and form a first layer;
depositing a second solution on a substrate with the inkjet printer;
drying the second solution to evaporate a solvent from the second deposited solution and form a second layer; and
scanning a heating device across the surface of the substrate to anneal the first layer and the second layer.

19. The method of claim 18, in which the step of depositing the first solution comprises depositing at least one of a solvated precursor to a functional material and a suspension of particles of a functional material.

20. The method of claim 18, in which the second solution is the same solution as the first solution.

21. The method of claim 18, in which the step of scanning the heating device comprises scanning at least one of a laser beam, a microwave heating device, and a Joule effect heating device.

22. The method of claim 21, in which the step of scanning the heating device across the surface comprises decomposing organic components of the first solution and the second solution.

23. The method of claim 21, further comprising a cleaning step with a liquid-solvent dispensing device after drying the first layer and before depositing the second layer.

24. The method of claim 18, further comprising heating the substrate before and during the step of depositing the first solution.

25. The method of claim 18, in which the steps of depositing the first solution and depositing the second solution comprise depositing at least one of a layer of a fuel cell, a component of a layer of a fuel cell, an electrolysis cell, and a solar cell.

26. The method of claim 18, in which the steps of depositing the first solution and depositing the second solution comprise depositing at least one of a layer of an electronic device and a component of a layer of an electronic device.
